(19) United States
(12) Patent Application Publication
(10) Pub. No.: US 2013/0104799 A1
(43) Pub. Date: May 2, 2013

(54) Shroud and Method for Adding Fluid to a Melt

(71) Applicants: Richard H. BERG, Hilton, NY (US); Richard D. HECKERT, Lewisburg, PA (US)

(72) Inventors: Richard H. BERG, Hilton, NY (US); Richard D. HECKERT, Lewisburg, PA (US)

(73) Assignee: SPX Corporation, Charlotte, NC (US)

(21) Appl. No.: 13/327,938

(22) Filed: Dec. 16, 2011

Related U.S. Application Data
(60) Provisional application No. 61/554,783, filed on Nov. 2, 2011.

(51) Int. Cl. C30B 11/12; C30B 11/10; C30B 11/02

(52) U.S. Cl. 117/77; 117/206; 117/73

(57) ABSTRACT

A shroud is provided. The shroud may include: a body defining a hollow space within the body, wherein the body is open at a bottom portion of the body to permit fluid communication between the hollow space and the outside of the body; an inlet and an outlet providing fluid communication through the body to the hollow space; a top portion of the body configured to provide a barrier between the hollow space and the outside of the body; and a baffle plate attached to the bottom portion of the body. A method for adding silicon to a silicon melt may be provided.

### CROSS-REFERENCE TO RELATED APPLICATIONS

This application claims priority to pending provisional U.S. patent application entitled, Gas Shroud and Method for Decomposing a Gas, filed Nov. 2, 2011, having a Ser. No. 61/554,783, the disclosure of which is hereby incorporated by reference in its entirety.

### FIELD OF THE INVENTION

The present invention relates generally to a method and apparatus for producing bottles of silicon. More particularly, the present invention relates to a shroud used in condensing silicon from a silicon gas or liquid and a corresponding method for decomposing silicon containing gas or separating silicon from liquid silicon.

### BACKGROUND OF THE INVENTION

Processed silicon is sold primarily to two industries, a semiconductor market and the photovoltaic industry. Silicon wafers are used in the production of solar panels in the photovoltaic market and for the production of microchips in the semiconductor market. One problem that remains in these markets is a shortage of polysilicon. Currently, silicon manufactures may produce quasi-monocast ingots which may have many impurities. Such impurities in a monocast silicon ingot is a nuisance for the wafer cutting machinery. Semiconductor companies cannot accept the impurities levels of monocast silicon. Therefore, silicon boules that are pure and single crystals are desired.

Accordingly, it is desirable to provide a method or apparatus that may be used in the production of silicon boules having a desired purity.

### SUMMARY OF THE INVENTION

The foregoing needs are met, to a great extent, by the present invention. In one aspect, an apparatus is provided that, in some embodiments, a method and apparatus is provided that is able to produce single crystal silicon bottles of a desired purity.

In accordance with one embodiment of the present invention a shroud is provided. The shroud may include: a body defining a hollow space within the body, wherein the body is open at a bottom portion of the body to permit fluid communication between the hollow space and the outside of the body; an inlet and an outlet providing fluid communication through the body to the hollow space; a top portion of the body configured to provide a barrier between the hollow space and the outside of the body; and a baffle plate attached to the bottom portion of the body.

In accordance with another embodiment of the present invention, a method for adding silicon to a silicon melt may be provided. The method may include: flowing a silicon fluid through a shroud wherein the shroud has: a body defining a hollow space within the body, wherein the body is open at a bottom portion of the body to permit fluid communication between the hollow space and the outside of the body; an inlet and an outlet providing fluid communication through the body to the hollow space; atop portion of the body configured to provide a barrier between the hollow space and the outside of the body; and a baffle plate attached to the bottom portion of the body; and separating silicon from the silicon fluid when the silicon fluid is exposed to a surface of the silicon melt.

In accordance with yet another embodiment of the present invention, a shroud may be provided. The shroud may include: means for containing a fluid defining a hollow space within the means for containing a fluid, wherein the means for containing a fluid is open at a bottom portion of the means for containing a fluid to permit fluid communication between the hollow space and the outside of the means for containing a fluid; an inlet and an outlet providing fluid communication through the body to the hollow space; a top portion of the means for containing a fluid configured to provide a barrier between the hollow space and the outside of the means for containing a fluid; and a means for baffling a fluid attached to the body.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to he understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily he utilized as a basis for the designing of other structures, methods and systems for carrying out the several purposes of the present invention. It is important, therefore, that the claims he regarded as including such equivalent constructions insofar as they do not depart from the spirit and scope of the present invention.

### BRIEF DESCRIPTION OF THE DRAWINGS

FIG. 1 is a perspective view of a gas shroud in accordance with an embodiment of the invention.

FIG. 2 is a perspective, cross-sectional view of a gas shroud in a crucible in accordance with an embodiment of the invention.

FIG. 3 is a cross-sectional view of the gas shroud in crucible in a heating apparatus in accordance with an embodiment of the invention.

FIG. 4 is a perspective view of a shroud in accordance with an embodiment of the invention.

FIG. 5 is a perspective, cross-sectional view of a shroud in accordance with an embodiment of the invention.

FIG. 6 is cross-sectional view of a shroud in accordance with an embodiment of the invention illustrating a warped or flexed position of the bottom baffle plate.

FIG. 7 is a perspective view of a shroud in accordance with another embodiment of the invention.

FIG. 8 is a perspective, cross-sectional view of the shroud shown in FIG. 7.

FIG. 9 is a partial cross-sectional of shroud in accordance with an embodiment of the invention.

FIG. 10 is a perspective, partial cross-sectional view of the shroud shown in FIGS. 7 and 8.

FIG. 11 is a cross-sectional view of shroud shown in FIGS. 7, 8 and 10 where the shroud is in a crucible in accordance with an embodiment of the invention.

FIG. 12 is a close up cross-sectional view of the shroud shown FIG. 11.

FIG. 13 is perspective view of a shroud in accordance with an embodiment of the invention.

FIG. 14 is perspective view of an underside of the shroud as shown in FIG. 13.

### DETAILED DESCRIPTION

The invention will now be described with reference to the drawing figures, in which like reference numerals refer to like parts throughout. An embodiment in accordance with the present invention allows a gas shroud to be used in condensing liquid silicon from a silicon gas source.

For example, a silicon ingot may be melted in a crucible and a silicon gas such as SiI₄ may flow over the silicon melt. The heat from the silicon melt may cause the SiI₄ gas to condense the silicon out of the gas into the melt and vent iodine gas. To facilitate this process, the Sit₄ gas must be exposed to the hot silicon melt in such a way to cause the silicon in the gas to condense out into the melt and not to be deposited on other portions of the heating apparatus. Furthermore, it is desired to control and/or contain the flow of the incoming SiI₄ gas and the outgoing iodine gas. In order to facilitate this process, a gas shroud may be used.

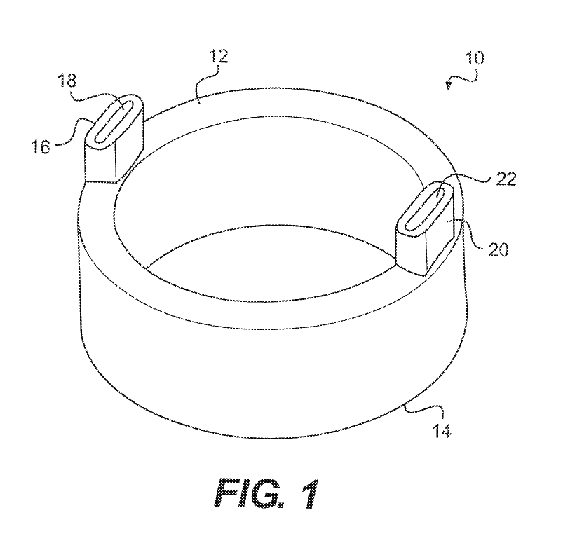

FIG. 1 illustrates a gas shroud 10 in accordance with some embodiments of the invention. A gas shroud 10 may be made of quartz. In sonic embodiments, quartz is used because it is chemically inert with respect to SiI₄ gas and the silicon melt in which the shroud 10 is partially immersed. The gas shroud 10 may be machined for a single piece of quartz or may be comprised of several pieces attached together.

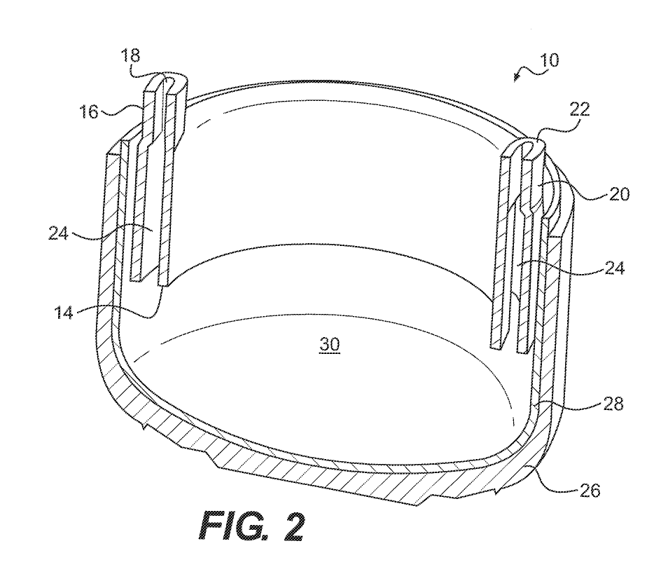

The shroud 10 includes atop 12 and a bottom 14. As shown in FIG. 2, the bottom 14 is open. Returning to FIG. 1, the shroud 10 is ring shaped or in the shape of an annulus. The shroud 10 may include an inlet 16 having an opening 18 to allow fluid communication through the top 12 into a shroud 10. The shroud 10 may also include an outlet 20 which also may include an opening 22 to permit fluid communication from the interior of the shroud 10 through the top 12.

As shown in FIG. 2, the shroud 10 may define a hollow interior space 24. The interior space 24 is in fluid communication with the opening 18 of the inlet 16 and the opening 22 of the outlet 20. The interior space 24 is also open as the bottom 14 of the gas shroud 10.

The gas shroud 10 is shown in FIG. 2 in a cross-section in order to better show the interior space 24. The gas shroud 10 is also shown in FIG. 2 in a crucible 26. The crucible 2.6 has a quartz liner 28 which may be used in the melting of silicon ingots as is known in the art. The gas shroud 10 has an outer diameter that is smaller than the inner diameter of the crucible 26 and the quartz liner 28. These relative dimensions permit the gas shroud 10 to fit, at least partially, in the crucible 26 and liner 28 without contacting each other as shown in FIG. 2.

The quartz liner 28 within the crucible 26 defines a melting chamber 30. Silicon ingots may be melted in the melting chamber 30. A quartz liner 28 may be used in order to eliminate or reduce chemical reactions between crucible 26 and the melted or liquid silicon.

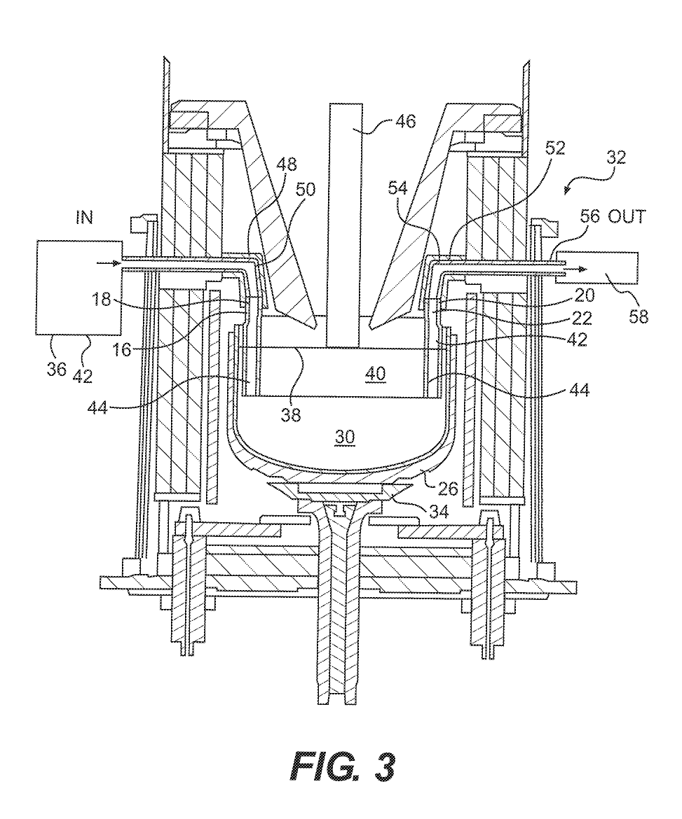

FIG. 3 shows a cross-sectional view of a gas shroud 10 and crucible 26 in a heating apparatus 32. The heating apparatus 32 may be substantially similar to most heating apparatuses used for melting silicon ingots in a crucible 26. However, the heating apparatus 32 shown in FIG. 3 has additional features in accordance with some embodiments of the invention which will be explained in detail later below.

The heating apparatus 32 includes a support 34 as shown in FIG. 3 to support the crucible 26. The support 34 is configured to support and rotate the crucible 26. Rotation of the crucible 26 while the ingot 46 is melted is well known and will not be discussed hereby in further detail. Below or near the support 34 may be burners or other heat producing elements which will not be described in detail as they are well known in the art.

In accordance with some embodiments of the invention, the operation shown in FIG. 3 of heating the ingot 46 to produce liquid silicon also referred to as the melt 40 may he augmented, or in other words, more liquid silicon may be produced by decomposing a silicon gas into the melting chamber 30 to produce additional liquid silicon. The silicon gas used for decomposing is provided by a silicon gas supply 36. The silicon gas in some embodiments may be SiI₄. Other silicon containing gases may also be used. The silicon gas supply 36 is placed in fluid communication with the gas shroud 10. As the silicon gas flows from the silicon gas supply 36 into the gas shroud 10, the silicon gas will decompose and allow liquid or condensed silicon to enter the melt 40.

The melt 40 has a top surface 38 which is depicted in FIG. 3 by a line and reference numeral 38. The silicon gas flows from the gas supply 36 through a gas flow path 42 and contacts the top surface 38 of the melt 40. The high temperatures that the silicon gas encounters causes the silicon gas to decompose condensing silicon out of the gas and adding to the material in the melt 40.

In some embodiments, the gas shroud 10 is partially submerged into the melt 40. Part of the melt material 40 is permitted to enter into the gas shroud 10 through the opened bottom surface 14. Thus, there is melt material 44 that is located in the gas shroud 10. By partially submerging the gas shroud 10 into the melt 40, the gas flow path 42 is substantially hermetically sealed as the gas cannot flow out of the opened bottom 14 into the melt material 44 in the gas shroud 10. Thus, the gas flows from the gas supply 36 through the inlet flow conduit 48 into the inlet 16 through the opening 18 through the gas flow path 42. While it is in the shroud 10 it encounters hot temperatures condensing the silicon out of the silicon gas, thus leaving iodine gas. The iodine gas then flows through the outlet 20 through the opening 22 into the outlet flow conduit 52.

While it would be appreciated by many of ordinary skill in the art, such process may not be a perfect process, and some silicon may remain in the gas and is vented through the outlet 20.

According to some embodiments of the invention, the gas shroud 10 may be supported by and attached to the inlet flow conduit 48 and outlet flow conduit 52. As shown in FIG. 3, the inlet flow conduit 48 includes a bend 50. In some embodiments of the invention this bend 50 may have a reduced angle from the sharp, nearly 90° angle which is shown in FIG. 3. In embodiments where reduced angles are used may provide advantages where, silicon may be deposited onto the sloped surface near where the bend 50 is shown in FIG. 3 and the sloped surface is sloped toward the inlet 16 opening 18 thereby causing the silicon to flow into the gas shroud 10 and add to the melt 40. Similarly, in some embodiments, the bend 54 and the outlet flow conduit 52 may also be a more gentler slope than that shown in FIG. 3. If silicon is deposited in the interior of the outlet flow conduit 52 the slope of the interior of the outlet flow conduit 52 may be such as the silicon will flow into the gas shroud 10 through the outlet 20 opening 22 and into the melt 40.

In the case of SiI₄ gas, after the silicon is distilled iodine gas remains. The iodine gas flows out of the system outlet 56 and into a depository 58 or any other desired location for the resultant gas. It should be noted that the gas shroud 10 does several things. The gas shroud 10 provides a way for SiI₄ gas to be exposed to hot temperatures, thereby allowing it to decompose and condense silicon out of the gas arid into a melt 40. The gas shroud 10 also allows the remaining gas to be vented out of the shroud 10. The system allows the silicon to be deposited in a desired location while still allowing the gas to be channeled appropriately.

One of ordinary skill in the art will understand that the shroud 10 will remain stationary, fixed and connected to the inlet flow conduit 48 and outlet flow conduit 52 or any other connections means, while the crucible 26 will be rotated. As such, the shroud 10 is dimensioned to be small enough to fit within the crucible 26 without contacting the crucible and thereby hindering the rotation of the crucible 26.

One of ordinary skill in the art after reading this disclosure will understand that the pressure of the gas supplied to the melt 40 should be controlled. This pressure should be controlled to avoid blowing the melt 40 out of the gas shroud 10 or crucible 26. Further, the pressure should be controlled to avoid drawing the melt 40 into the gas shroud 10 to an undesirable degree.

An example of the silicon melt and gas decomposing process will be described briefly below. If Si₂I₄ gas is flowing at an 150 kilograms per hour, its decomposition will occur at a melt surface at 4.8 kilograms of silicon per hour. This is to match the 63 millimeters per hour pull rate at a 8 inch diameter crystal. The exit will be iodine gas. The following equation below will express this and show that the mass balance works appropriately. Equations below are merely meant to be exemplary and are not limiting.

$$Growth\_Rate \_KX := 63 \cdot \frac{mm}{hr}$$

$$Dia\_ingot := 205 \cdot mm = 8.071 \cdot in \\ This is growth rate for an 8 inch diameter ingot . \\ Area\_ingot := π \cdot \frac{{( Dia\_ingot )}^{2}}{4} = 0.033 \cdot {m}^{2}$$

$${ρ}_{solid\_Si} := 2340 \cdot \frac{kg}{{m}^{3}}$$

$$\begin{matrix}{mass\_flow}_{solid \_ KX} := Growth\_Rate \_KX \cdot Area\_ingot \cdot {ρ}_{solid \_ Si} \\ = 4.866 \cdot \frac{kg}{hr}\end{matrix}$$

$$Mass Growth Rate for the Ingot . \\ Flow Rate 150 kg \text{/} hr produces 4.8 kg of liquid Si$$

$$Decomposition Surface Area$$

$$Gas Shroud$$

$${OD}_{gs} := 23. \cdot in \\ {ID}_{gs} := 21.5 \cdot in \\ Area := \frac{π \cdot ( {OD}_{gs}^{2} - {ID}_{gs}^{2} )}{4} = 0.034 {m}^{2} \\ {V}_{y} := \frac{{mass\_flow}_{solid\_KX}}{{ρ}_{solid\_Si} - Area} = 61.479 \cdot \frac{mm}{hr}$$

$$Ro := \frac{( {OD}_{gs} - {ID}_{gs} )}{2} + {ID}_{gs} = 565.15 \cdot mm$$

The embodiment of the shroud 10 shown in FIGS. 1-3 is primarily directed to embodiments where the silicon supplied to the shroud 10 is in gaseous form. In other embodiments, the silicon maybe supplied to a shroud 10 in liquid form. For example, with reference to FIG. 3, the silicon supply 36 may supply liquid silicon as liquid SiI₄. Other forms of liquid silicon may also be used.

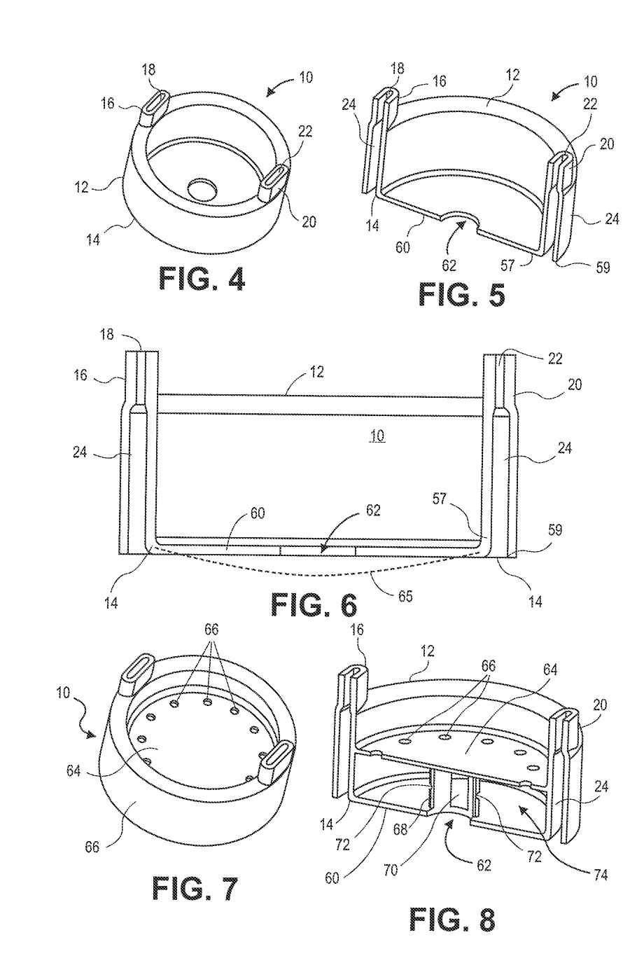

The SiI₄ liquid may flow through the flow path 42 around the bend 50 and into the inlet 16 via the inlet opening 18. In such an instance, a different type of shroud may be used as shown, for example, in FIGS. 4-14. These various different shrouds 10 will be discussed further below. When the liquid contacts the melt 40, a reaction may occur. In some embodiments, some, but not necessarily all, of the silicon may come out of the SiI₄ and be added to the melt 40. Iodine gas maybe generated as a result of some of the silicon leaving the SiI₄ liquid and flow through the interior 24 of the shroud 10 and out of the outlet 20 through the outlet opening 22 through the system outlet 56 and into a depository 58. In some embodiments of the invention, not only iodine gas will flow out the system outlet 56 but also some SiI₄ gas and/or liquid.

In embodiments where the fluid supplied to the shroud 10 is in liquid form, a shroud 10, as shown in FIG. 4-6 may be used, FIG. 4 illustrates a perspective view of the shroud 10. FIG. 5 is a perspective cross-sectional view and FIG, 6 illustrates a cross-sectional view of the shroud 10. As shown in FIGS, 4-6, the shroud 10 includes a top 12 and bottom 14, inlet 16 having an inlet opening 18 and outlet 20 with an outlet opening 22. The shroud 10 may be composed of quartz as described with the shroud 10 illustrated and described with respect to FIGS. 1-3.

The shroud 10 may be very similar to the embodiment shown in FIGS. 1-3, but may have an additional feature of a bottom baffle plate 60 attached to the bottom portion 14 of the shroud 10. As shown in FIGS. 4-6 the bottom baffle plate 60 may include a hole 62 in the baffle plate 60. The baffle plate 60 may be attached to the lower inner wall 57 at a position opposite of the lower outer wall 59. The purpose of the baffle plate 60 and hole 62 in the baffle plate 60 is to reduce flow or disturbance of the melt 40 which may be caused when liquid silicon is supplied to the melt 40 via the inlet 16. The flow of the liquid coming into the melt 40 may disturb the melt 40 and cause turbulence or flow, having the shroud 10 partially submerged in the melt 40 as well as the baffle plate 60 with the hole 62 will tend to dampen any flow or disturbance in the melt 40.

In some embodiments of the invention, the high temperature of the melt 40 may cause the bottom baffle plate 60 to sag. An exaggerated illustration of the sagging is shown by dashed line 65 in FIG. 6.

Another embodiment of the invention is illustrated in FIGS. 7-12. As shown in FIGS. 7 and 8, the shroud 10 may include a second baffle plate 64 located at a mid-position within the shroud 10. The second baffle plate 64 may include holes 66 and maybe located above the lower baffle plate 60. The holes 66 may be of any shape such as, but not limited to, circles, ovals, ellipses or any other suitable shape. Column 68 maybe located in an annular arrangement around the hole 62 and configured to connect the lower baffle plate 60 to the mid or second baffle plate 64 as shown in FIGS. 8, 10, 11 and 12.

The shroud 10 of the embodiment shown FIGS. 7 and 8 has features similar to the other shrouds including the inlet 16, the outlet 20, the top portion 12, the bottom portion 14 and the hollow interior space 24 and other common features. One purpose of the additional baffle plate 64 (or in some embodiments, a series of baffle plates) is to aid in reducing movement or flow of the melt 40 by adding additional baffling to reduce any disturbance of liquid flowing into the melt 40 via the inlet 16.

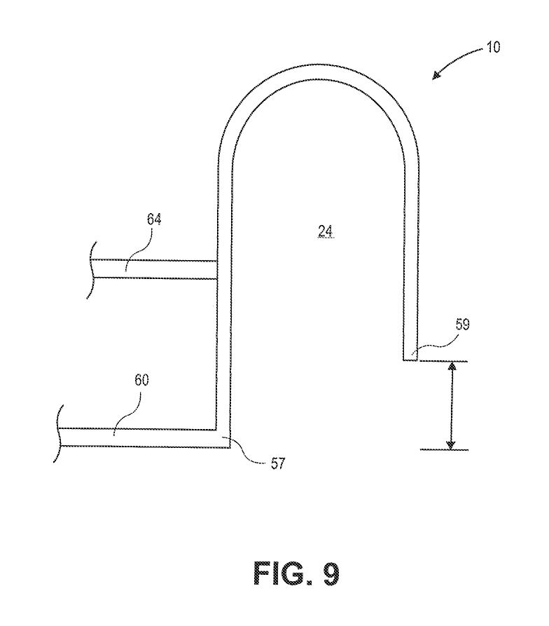

FIG. 9 is a partial cross-sectional view the portion of the shroud 10 shown in FIGS. 7, 8, 10, 11 and 12. As shown in FIG. 9, the lower outer wall 59 may not extend as far down as the lower inner wall 57. The difference is illustrated by Arrow A. By selecting the geometry and measurements of the lower outer wall 59 to be higher than the lower inner wall 57 certain thermodynamic advantages may be achieved. The lower outer wall 59 still does form a hollow inner space 24 and will typically be submerged within the melt 40 along with the baffle plates 60 and 64. Also the arrangement of having the lower inner wall 57 extend below the end of the lower outer wall 59 can also be used in embodiments for only a lower baffle plate 60 or where no baffle plate is used such as the embodiment shown in FIGS. 1 and 2.

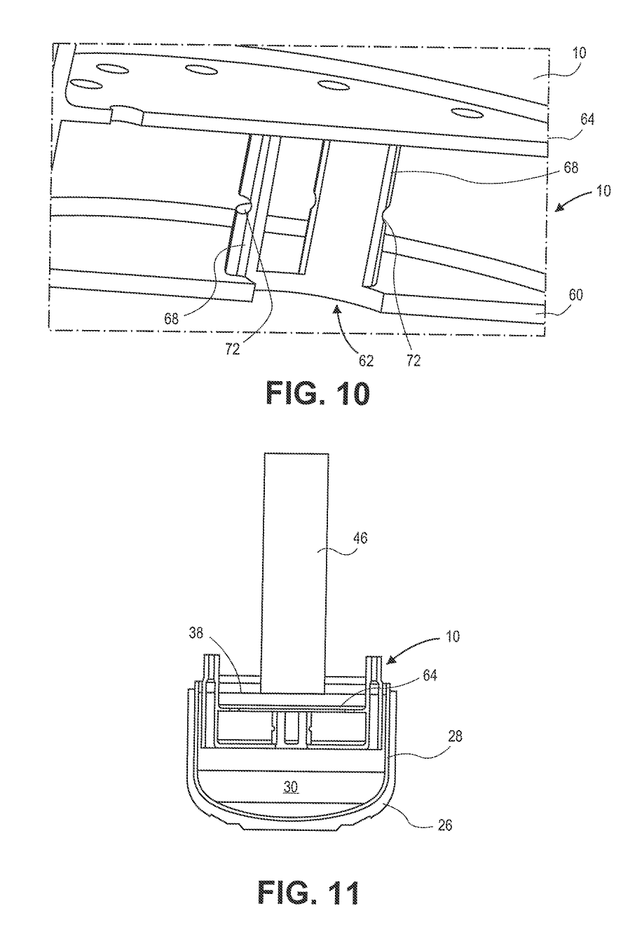

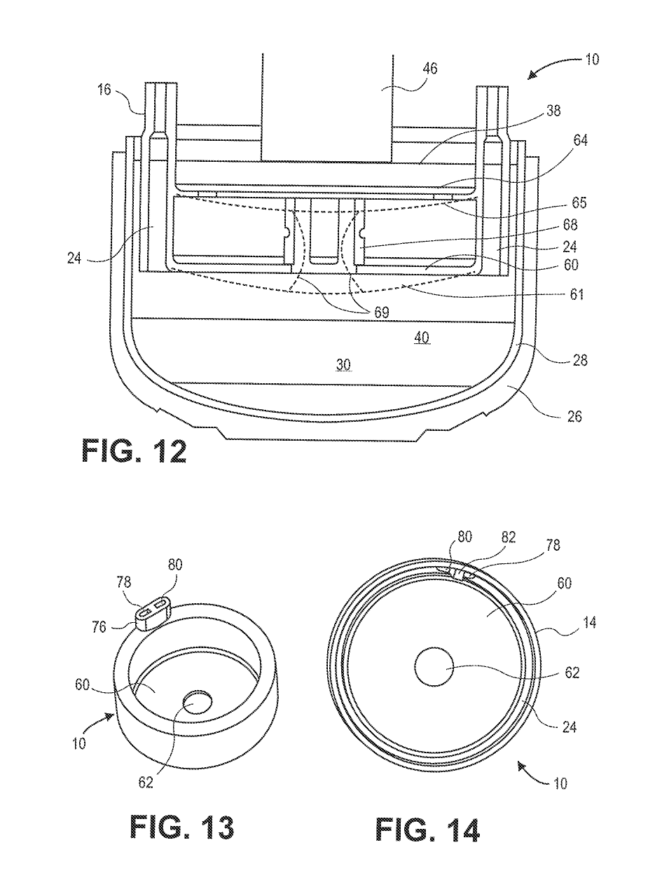

FIG. 10 is close up partial perspective view showing the column 68 attaching the upper mid baffle plate 64 with the lower baffle plate 60 in the shroud 10. The column 68 may be located in annular pattern around the hole 62 and in some embodiments may include a notch 72 which helps to bend the columns in a desired way as shown in dash lines 69 in FIG. 12 when the columns are subject to heat.

FIG. 11 illustrates a shroud 10 located within a crucible 26 having a quartz liner 28. A silicon wafer or ingot 46 is also illustrated. The wafer or ingot 46 is usually placed in contact with the melt 40 (see FIG. 3). The melting chamber 30 includes a portion below shroud 10 within the crucible 26 and quartz liner 28 and extends upward to approximately where the bottom of the ingot 46 resides.

An enlarged partial view of the FIG. 11 is shown in FIG. 12. The shroud 10 is placed within the quartz liner 28 set within the crucible 26.

The melting chamber 30 contains the melt 40. The shroud 10 is placed partially within the melt 40. The top surface 38 of the melt is shown by line 38. The top surface 38 of the melt 40 is contacted by the ingot 46, in some embodiments of the invention, the ingot 46 contacts the top surface 38 of the melt 40 at about an 11° degree angle. The shroud 10 is submerged within the melt 40 so the part of the melt 40 is located within the hollow interior space 24 of the shroud 10. The bottom baffle plate 60 and the upper baffle plate or mid baffle plate 64 are submerged within the melt 40. Due to the high temperature of the melt 40, the bottom baffle plate 60 and the mid baffle plate 64 may sag. The sagging of these plates 60 and 64 are illustrated by dash lines 61 and 65 respectively. The column 68 have buckled inwardly as illustrated by dash lines 69.

Dashed lines 61, 65 and 69 are for illustrative purposes, and may be exaggerated. The Dashed lines 61, 65, and 69 are not intended to show or illustrate an amount that the plates 60, 61 and columns 68 may sag. Buckling of the column 68 may be facilitated by the presence of the notches 72. The notches 72 create weak places in the columns 68 causing the columns 68 to bend in a desired way. One of the purposes for the notches 72 is to maintain uniform axisymmetric deflection so fluid inflow does not affect for reduce) the heating uniformity. Non heating uniformity can create different melt convection currents that may affect the quality of the ingot 46 at the melt interface 38. This could change the stress and resistivity of the ingot 46. One of ordinary skill in the art after reviewing this disclose may determine questions of how, where, how big or even if at all to use the notices 68 to achieve a desired result.

The baffle plates 60 and 64 help reduce disturbances in the melt 40 and/or dampen any disturbance in the melt 40 caused by fluid flowing into the melt 40 via the inlet 16. To an extent, the columns 68, holes 62 and 66 also help dampen the melt 40. The plates 60 and 64 and columns 68 may act to dampening even when they are sagging. The baffle plates 60 and 64 wall may he by design intentionally domed or from sagging of the quartz material due to high temperatures. The additional benefit of the dome or uniformly deformed baffles 50 and 64 is assist in the rejecting entrained bubbles from the pouring of the liquid SiI₄. The dome surfaces 61 and 65 will assist in repelling the bubbles back upwards rather making the inner wall 57 even longer.

FIGS. 13-14 illustrate an alternate embodiment in accordance with the invention. FIGS. 13 and 14 show a combined inlet/outlet 76. The combined inlet/outlet 16 contains both an inlet passage 78 and an outlet passage 80. By locating the inlet passage 78 and the outlet passage 80 near the same location at a combined outlet/inlet 76, any fluid flowing into the inlet 76 has additional time to contact the surface 38 of the melt 40 and will contact additional surface 38 area of the melt 40. Contacting more surface 38 area and having more time may help in causing a reaction of separating silicon from the silicon gas or liquid whichever the case may be. In the embodiment shown in FIGS. 13 and 14, the silicon fluid must travel almost 360° degrees around the shroud 10 to reach the outlet 80, whereas in the other embodiments described above, the fluid need only travel approximately 180° degrees around the shroud 10.

As shown in FIGS. 13 and 14, a bottom baffle plate 60 and hole 62 are included on the shroud 10. FIG. 14 is a rear or bottom view of the shroud 10 illustrating the hollow interior space 24, the bottom baffle plate 60 and the hole 62 attached to the bottom portion 14 e shroud 10. A divider 82 divides and provides separation within the hollow interior space 24 between the inlet passage 78 and the outlet passage 80. One of ordinary skilled in the art after reading this disclosure will appreciate that the divider 82 prevents fluid from flowing into the inlet passage 78 and directly into the outlet passage 80. Because of the divider 82 incoming fluid must flow completely around the shroud 10 through the hollow interior space 24 to reach the outlet passage 78.

One of ordinary skilled in the art after reading this disclosure will also appreciate that embodiments having combined inlet and outlet 76 may also be used where there is no baffle plate similar to that shown in FIG. 1 and embodiments where multiple baffle plates are used similar to that embodiment shown in FIGS. 7-12.

The many features and advantages of the invention are apparent from the detailed specification, and thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

What is claimed is:

1. A shroud comprising:
a body defining a hollow space within the body, wherein the body is open at a bottom portion of the body to permit fluid communication between the hollow space and the outside of the body;
an inlet and an outlet providing fluid communication through the body to the hollow space;
a top portion of the body configured to provide a barrier between the hollow space and the outside of the body; and
a baffle plate attached to the bottom portion of the body.

2. The shroud of claim 1, wherein the body is made of quartz.

3. The shroud of claim 1, wherein the baffle plate includes a hole through the plate.

4. The shroud of claim 3, further comprising a second baffle plate located above the first baffle plate and attached to the first baffle plate via columns.

5. The shroud of claim 4, further comprising bending notches in the columns located in a position to encourage the columns to bend in a desired direction when the columns are subjected to a compressive force.

6. The shroud of claim 4, further comprising holes in the second baffle plate.

7. The shroud of claim 1, wherein the baffle plate is configured to sag when exposed to a silicon melt.

8. The shroud of claim 1, wherein the body is annular in shape.

9. The shroud of claim 1, wherein the inlet and the outlet are located on the body to provide a fluid pathway through the top portion.

10. The shroud of claim 1, wherein a lower outer wall on the shroud does not extend as far down on the shroud as the lower inner wall and the baffle plate.

11. The shroud of claim 1 wherein the inlet is located adjacent to the outlet.

12. A method for adding silicon to a silicon melt comprising:
flowing a silicon fluid through a shroud wherein the shroud has:
a body defining a hollow space within the body, wherein the body is open at a bottom portion of the body to permit fluid communication between the hollow space and the outside of the body;
an inlet and an outlet providing fluid communication through the body to the hollow space;
a top portion of the body configured to provide a barrier between the hollow space and the outside of the body; and
a baffle plate attached to the bottom portion of the body; and
separating silicon from the silicon fluid when the silicon fluid is exposed to a surface of the silicon melt.

13. The method of claim 12, wherein the fluid is either a silicon gas or liquid.

14. The method of claim 13, further comprising partially submersing the shroud in a silicon melt.

15. The method of claim 14, further comprising holding the shroud static and rotating a container holding the liquid silicon.

16. The method of claim 14, further comprising allowing the baffle plate to sag.

17. The method of claim 16, further comprising: bending columns connecting the baffle plate with a second baffle plate at a notch in the columns.

18. The method of claim 14, further comprising contacting a silicon ingot with the liquid silicon.

19. The method of claim 12, further including forming the shroud from quartz.

20. A shroud comprising:
means for containing a fluid defining a hollow space within the means for containing a fluid, wherein the means for containing a fluid is open at a bottom portion of the means for containing a fluid to permit fluid communication between the hollow space and the outside of the means for containing a fluid;
an inlet and an outlet providing fluid communication through the body to the hollow space;
a top portion of the means for containing a fluid configured to provide a barrier between the hollow space and the outside of the means for containing a fluid; and
a means for baffling a fluid attached to the body.
